(19) United States
(12) Patent Application Publication
(10) Pub. No.: US 2023/0228820 A1
(43) Pub. Date: Jul. 20, 2023

(54) BATTERY CAPACITY DISPLAY METHOD AND DEVICE, ELECTRONIC EQUIPMENT AND STORAGE MEDIUM

(71) Applicant: GOERTEK INC., Shandong (CN)

(72) Inventors: Kai LIU, Shandong (CN); Wenfeng LI, Shandong (CN)

(73) Assignee: GOERTEK INC., Shandong (CN)

(21) Appl. No.: 17/996,450

(22) PCT Filed: Dec. 15, 2020
(86) PCT No.: PCT/CN2020/136333

§ 371 Date: Oct. 18, 2022

(30) Foreign Application Priority Data
Apr. 30, 2020 (CN) 202010365386.1

(51) Int. Cl. G01R 31/36; G01R 31/388; H01M 10/48; G01R 31/3842

(52) U.S. Cl. CPC G01R 31/3646; G01R 31/388; H01M 10/488; G01R 31/3842

(57) ABSTRACT

A battery capacity display method and device, electronic equipment and a computer-readable storage medium are disclosed. The method comprises: judging whether a battery to be detected can be fully charged when the battery to be detected is in a constant voltage charging state (S101); if not, determining a current capacity state of the battery to be detected and monitoring a time duration of the battery to be detected under the current capacity state (S102); judging whether the time duration is greater than a corresponding preset overtime threshold (S103); and if the time duration is greater than the preset overtime threshold, displaying full capacity via a UI interface (S104).

### CROSS-REFERENCE TO RELATED APPLICATIONS

This Application is a U.S. National-Stage entry under 35 U.S.C. § 371 based on International Application No. PCT/CN2020/136333, filed Dec. 15, 2020 which was published under PCT Article 21(2) and which claims priority to Chinese Application No. 202010365386.1, filed Apr. 30, 2020, which are all hereby incorporated herein in their entirety by reference.

### TECHNICAL FIELD

This application pertains to the technical field of electronic equipment, more specifically to a battery capacity display method and device, electronic equipment and a computer-readable storage medium.

### BACKGROUND

It is well know that after consumer electronic products are used for a long time, there will inevitably be battery loss to a corresponding extent, which will lead to the failure to correctly display the fully charged state during charging, thereby making users confused and bringing them poor use experience.

Therefore, those skilled in the art need to pay attention to how to solve the above problems. In addition, other objects, desirable features and characteristics will become apparent from the subsequent summary and detailed description, and the appended claims, taken in conjunction with the accompanying drawings and this background.

### SUMMARY

The object of the present disclosure is to provide a battery capacity display method and device, electronic equipment and a computer-readable storage medium, which significantly improves the user experience.

In order to achieve the above object, the present disclosure provides a battery capacity display method, comprising:

judging whether a battery to be detected can be fully charged when the battery to be detected is in a constant voltage charging state;

if not, determining a current capacity state of the battery to be detected and monitoring a time duration of the battery to be detected under the current capacity state;

judging whether the time duration is greater than a corresponding preset overtime threshold; and

if the time duration is greater than the preset overtime threshold, displaying full capacity via a UI interface.

Optionally, the step of judging whether the battery to be detected can be fully charged comprises:

acquiring a current voltage value of the battery to be detected;

judging whether the current voltage value reaches a preset voltage threshold; and

if yes, determining that the battery to be detected can be fully charged.

Optionally, the step of judging whether the battery to be detected can be fully charged comprises:

if the battery to be detected is equipped with a capacity meter, directly acquiring a current capacity value of the battery to be detected obtained by the capacity meter;

judging whether the current capacity value reaches a preset capacity threshold; and

if yes, determining that the battery to be detected can be fully charged.

After determining the current capacity state of the battery to be detected, the method further comprises:

determining a capacity range in which a capacity value corresponding to the current capacity state is located;

correspondingly, if the time duration is greater than the preset overtime threshold, displaying full capacity via the UI interface, comprises:

if the time duration is greater than the preset overtime threshold and the capacity value corresponding to the current capacity state is in a first capacity range, directly displaying full capacity via the UI interface;

if the time duration is greater than the preset overtime threshold and the capacity value corresponding to the current capacity state is in a second capacity range, displaying a first prompt message of battery loss and displaying full capacity via the UI interface; and

if the time duration is greater than the preset overtime threshold and the capacity value corresponding to the current capacity state is in a third capacity range, sending back a second prompt message of serious battery loss and displaying full capacity via the UI interface.

Optionally, after judging whether the battery to be detected can be fully charged, the method further comprises:

if it is determined that the battery to be detected can be fully charged, directly displaying full capacity via the UI interface.

Optionally, the method further comprises:

collecting a plurality of historical charging curves of the battery to be detected, and determining an initial overtime threshold corresponding to each historical charging curve; and

determining an average value of a plurality of initial overtime thresholds as the preset overtime threshold.

In order to achieve the above object, the present disclosure provides a battery capacity display device, comprising:

a first judgment module for judging whether a battery to be detected can be fully charged when the battery to be detected is in a constant voltage charging state;

a time monitoring module for, if it is determined that the battery to be detected can be fully charged, determining a current capacity state of the battery to be detected and monitoring a time duration of the battery to be detected under the current capacity state;

a second judgment module for judging whether the time duration is greater than a corresponding preset overtime threshold; and

a full capacity display module for, if the time duration is greater than the preset overtime threshold, displaying full capacity via a UI interface.

Optionally, the first judgment module comprises:

an acquisition unit for acquiring a current voltage value of the battery to be detected;

a judgment unit for judging whether the current voltage value reaches a preset voltage threshold; and

a determination unit for determining that the battery to be detected can be fully charged if the current voltage value reaches the preset voltage threshold.

To achieve the above object, the present disclosure provides electronic equipment, comprising:

a memory for storing a computer program; and

a processor for realizing steps of any of the battery capacity display methods as described above when executing the computer program.

In order to achieve the above object, the present disclosure provides a computer-readable storage medium on which a computer program is stored. When the computer program is executed by a processor, the steps of any of the battery capacity display methods disclosed above are realized.

It can be seen from the above solution that, the battery capacity display method according to the present disclosure comprises: judging whether a battery to be detected can be fully charged when the battery to be detected is in a constant voltage charging state; if not, determining a current capacity state of the battery to be detected and monitoring a time duration of the battery to be detected under the current capacity state; judging whether the time duration is greater than a corresponding preset overtime threshold; and if the time duration is greater than the preset overtime threshold, displaying full capacity via a UI interface. It can be seen from the above that, the present disclosure can judge whether the battery to be detected can be fully charged when the battery is charged at a constant voltage. If it cannot be fully charged, i.e., there is a battery loss, full capacity is displayed via the UI interface when the time duration of the battery in the current capacity state reaches the preset overtime threshold, so that the fully charged state can be still correctly displayed even when there is a battery loss, thereby significantly improving the user experience.

The present disclosure also discloses a battery capacity display device, electronic equipment and a computer-readable storage medium, which can also achieve the above technical effects.

It should be understood that the above general description and the following detailed description are only exemplary and do not limit the present disclosure.

### BRIEF DESCRIPTION OF DRAWINGS

The present invention will hereinafter be described in conjunction with the following drawing figures, wherein like numerals denote like elements, and:

FIG. 1 is a flowchart of a battery capacity display method according to an embodiment of the present disclosure;

FIG. 2 is a flowchart of another battery capacity display method according to an embodiment of the present disclosure;

FIG. 3 is a schematic diagram of the structure of a battery capacity display device according to an embodiment of the present disclosure;

FIG. 4 is a schematic diagram of the structure of electronic equipment according to an embodiment of the present disclosure; and

FIG. 5 is a schematic diagram of the structure of another electronic equipment according to an embodiment of the present disclosure.

### DETAILED DESCRIPTION

The following detailed description is merely exemplary in nature and is not intended to limit the invention or the application and uses of the invention. Furthermore, there is no intention to be bound by any theory presented in the preceding background of the invention or the following detailed description.

The technical solutions in embodiments of the present disclosure will be described clearly and completely below with reference to the drawings in the embodiments of the present disclosure. Obviously, the embodiments as described below are merely part of, rather than all, embodiments of the present disclosure. Based on the embodiments of the present disclosure, any other embodiment obtained by a person of ordinary skill in the art without paying any creative effort shall fall within the protection scope of the present disclosure.

In the prior art, after consumer electronic products are used for a long time, there will inevitably be battery loss to a corresponding extent, which will lead to the failure to correctly display the fully charged state during charging, thereby making users confused and bringing them poor use experience.

Therefore, the embodiments of the present disclosure disclose a battery capacity display method, which significantly improves the user experience.

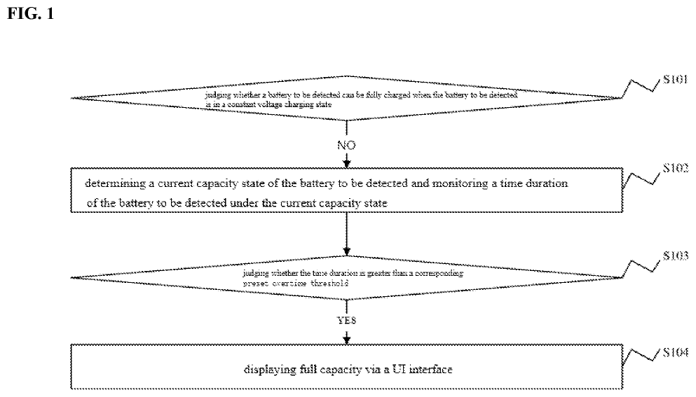

As shown in FIG. 1, an embodiment of the present disclosure discloses a battery capacity display method, which comprises:

S101: judging whether a battery to be detected can be fully charged when the battery to be detected is in a constant voltage charging state; if not, proceed to step S102;

In the embodiment of the present disclosure, it will be judged whether the battery to be detected can be fully charged when the battery to be detected is in a constant voltage charging state.

In a feasible embodiment, if a capacity meter is not installed, when judging whether the battery to be detected can be fully charged, it needs to acquire the current voltage value of the battery to be detected and judge whether the current voltage value reaches the preset voltage threshold. If the current voltage value reaches the preset voltage threshold, it is determined that the battery to be detected can be fully charged. The above preset voltage threshold may specifically be the voltage value corresponding to the full capacity, which can be set according to the actual situation in the specific implementation, and it is not particularly limited here.

In another feasible embodiment, if the battery to be detected is equipped with a capacity meter, the current capacity value of the battery to be detected can be detected by the capacity meter, so that the current capacity value can be directly acquired, and it can be judged whether the current capacity value reaches the preset capacity threshold. If the current capacity value reaches the preset capacity threshold, it is determined that the battery to be detected can be fully charged. The above preset capacity threshold may specifically be a full capacity value, which can be set according to the actual situation in the specific implementation, and it is not particularly limited here.

S102: determining a current capacity state of the battery to be detected and monitoring a time duration of the battery to be detected under the current capacity state;

In this step, if it is determined that the battery to be detected cannot be fully charged by the above steps, the current capacity state of the battery to be detected is acquired, and time counting is started to detect the time duration of the battery to be detected under the current capacity state.

It is understandable that if it is determined that the battery to be detected can be fully charged by the above steps, the full capacity can be directly displayed in the battery capacity display area via the UI interface.

S103: judging whether the time duration is greater than a corresponding preset overtime threshold; if yes, proceed to step S104;

It should be noted that in this step it will be monitored whether the time duration exceeds the corresponding preset overtime threshold. The preset overtime threshold may correspond to the battery capacity state, that is, different capacity states may correspond to different time thresholds.

Specifically, a plurality of historical charging curves of the battery to be detected may be collected, and an initial overtime threshold corresponding to each historical charging curve is determined, and then an average value of a plurality of initial overtime thresholds is determined as the preset overtime threshold. That is, the overtime threshold may be obtained by calculating a difference value based on the charging curve of the selected battery, the requirements for the CV constant voltage charging time and the time duration from entering the CV constant voltage charging state to reaching 99% of the battery capacity. For example, the time duration t1 when the capacity is increased from 50% to 100% and the time duration t2 when the capacity is increased from 50% to 99% is acquired, and the overtime threshold is t1 minus t2. This difference value may also be an average value obtained based on multiple charging curves so as to improve the accuracy of the results. The above CV constant voltage charging time duration may be set according to demand, for example, it may be set that the constant voltage stage starts when the capacity reaches 50%.

S104: displaying full capacity via a UI interface.

It is understandable that if it is monitored that the time duration of the battery to be detected under the current capacity state exceeds the preset overtime threshold, the full capacity can be displayed in the corresponding display area via the UI interface, so that the situation that the full capacity cannot be displayed during charging when there is a battery loss can be avoided. In the specific implementation, an indicator for overtime full capacity may be set. When the capacity management module detects this indicator, it may send a corresponding notification to the UI module to display full capacity via the UI interface.

It can be seen from the above solution that the battery capacity display method according to the present disclosure comprises: judging whether a battery to be detected can be fully charged when the battery to be detected is in a constant voltage charging state; if not, determining a current capacity state of the battery to be detected and monitoring a time duration of the battery to be detected under the current capacity state; judging whether the time duration is greater than a corresponding preset overtime threshold; and if the time duration is greater than the preset overtime threshold, displaying full capacity via a UI interface. It can be seen from the above that, the present disclosure can judge whether the battery to be detected can be fully charged when the battery is charged at a constant voltage. If it cannot be fully charged, i.e., there is a battery loss, full capacity is displayed via the UI interface when the time duration of the battery in the current capacity state reaches the preset overtime threshold, so that the fully charged state can be still correctly displayed even when there is a battery loss, thereby significantly improving the user experience.

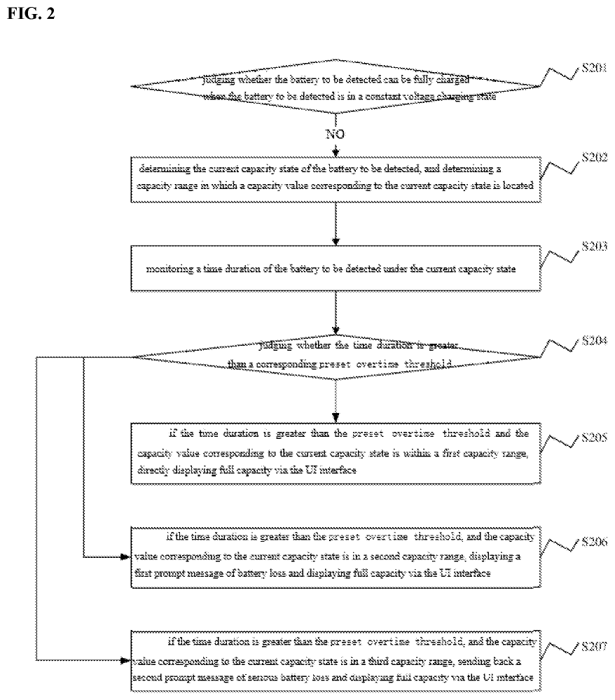

The embodiment of the present disclosure discloses another battery capacity display method. Compared with the previous embodiment, this embodiment further explains and optimizes the technical solution. Referring to FIG. 2, specifically,

S201: judging whether the battery to be detected can be fully charged when the battery to be detected is in a constant voltage charging state; if not, proceed to step S202;

S202: determining the current capacity state of the battery to be detected, and determining a capacity range in which a capacity value corresponding to the current capacity state is located;

S203: monitoring a time duration of the battery to be detected under the current capacity state;

S204: judging whether the time duration is greater than a corresponding preset overtime threshold;

S205: if the time duration is greater than the preset overtime threshold and the capacity value corresponding to the current capacity state is within a first capacity range, directly displaying full capacity via the UI interface;

S206: if the time duration is greater than the preset overtime threshold, and the capacity value corresponding to the current capacity state is in a second capacity range, displaying a first prompt message of battery loss and displaying full capacity via the UI interface; and

S207: if the time duration is greater than the preset overtime threshold, and the capacity value corresponding to the current capacity state is in a third capacity range, sending back a second prompt message of serious battery loss and displaying full capacity via the UI interface.

In this embodiment of the present disclosure, a corresponding capacity range may be preset according to the degree of battery loss, and the corresponding degree of battery loss may be obtained according to the current continuous capacity state of the battery to be detected.

Specifically, the capacity range may be divided into the first capacity range, the second capacity range and the third capacity range. If the capacity value which the battery keeps a time duration that exceeds the preset overtime threshold during charging, it indicates that there is almost no battery loss, or the loss can be ignored. At this point, the full capacity can be directly displayed via the UI interface. If the capacity value is in the second capacity range, it indicates that the battery has a certain loss, but the impact on normal use is small. Therefore, the full capacity may be displayed via the UI interface, and the first prompt message of battery loss is sent back, and then the first prompt message is displayed in a preset prompt area. If the capacity value is in the third capacity range, it means that the battery loss is large, which may affect the normal use of the device. Therefore, the second prompt message of serious battery loss may be sent back while the full capacity is displayed via the UI interface. In the specific implementation, the second prompt message may be prompted through UI interface display, voice broadcast, etc.

A battery capacity display device according to an embodiment of the present disclosure will be described below. The battery capacity display device described below and the battery capacity display method described above can be referred to each other.

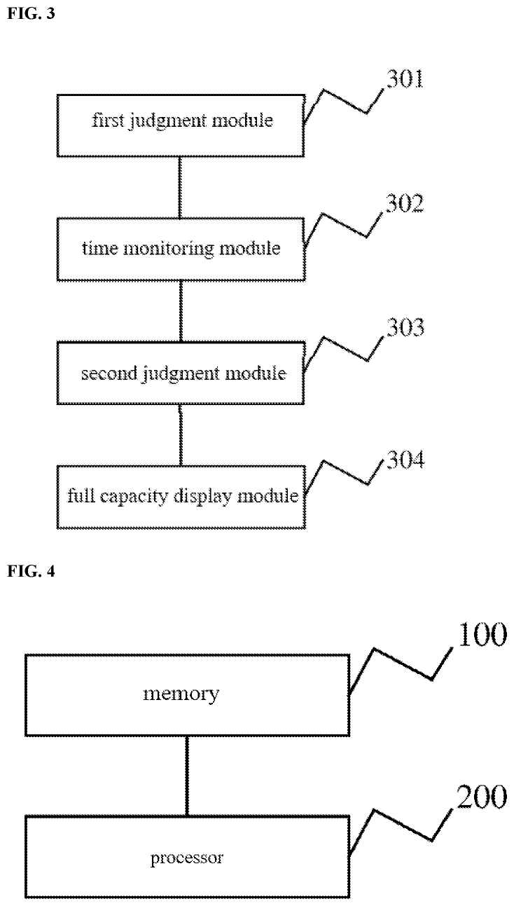

As shown in FIG. 3, the battery capacity display device according to an embodiment of the present disclosure comprises:

a first judgment module 301 for judging whether a battery to be detected can be fully charged when the battery to be detected is in a constant voltage charging state;

a time monitoring module 302 for, if it is determined that the battery to be detected can be fully charged, determining a current capacity state of the battery to be detected and monitoring a time duration of the battery to be detected under the current capacity state;

a second judgment module 303 for judging whether the time duration is greater than a corresponding preset overtime threshold; and

a full capacity display module 304 for, if the time duration is greater than the preset overtime threshold, displaying full capacity via a UI interface.

The specific implementation process of the above modules 301 to 304 may refer to the specific contents disclosed in the above embodiments, and will not be repeated here.

On the basis of the above embodiments, as a preferred embodiment, the first judgment module 301 according to an embodiment of the present disclosure may specifically comprise:

an acquisition unit for acquiring a current voltage value of the battery to be detected;

a judgment unit for judging whether the current voltage value reaches a preset voltage threshold; and

a determination unit for determining that the battery to be detected can be fully charged if the current voltage value reaches the preset voltage threshold.

The present disclosure also provides electronic equipment, as shown in FIG. 4. The electronic equipment according to an embodiment of the present disclosure comprises:

a memory 100 configured to store a computer program; and

a processor 200 configured to realize the steps provided by the above embodiments when executing the computer program.

Specifically, the memory 100 comprises a nonvolatile storage medium and an internal memory. The nonvolatile storage medium stores an operating system and computer-readable instructions, and the internal memory provides an environment for the operation of the operating system and computer-readable instructions in the nonvolatile storage medium. In some embodiments, the processor 200 may be a central processing unit (CPU), controller, microcontroller, microprocessor or other data processing chip, which provides computing and control capabilities for electronic equipment. When executing the computer program stored in the memory 100, the steps of the battery capacity display method disclosed in any of the foregoing embodiments can be realized.

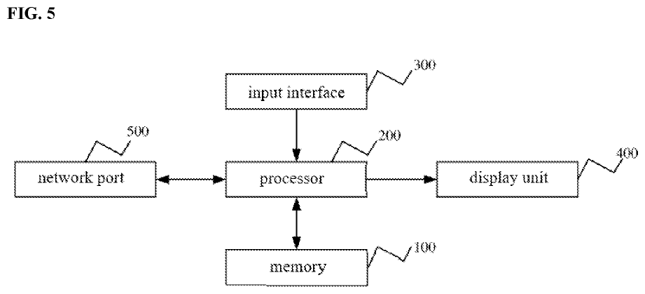

On the basis of the above embodiments, as a preferred embodiment, as shown in FIG. 5, the electronic equipment further comprises:

an input interface 300 connected to the processor 200 and configured to obtain externally imported computer programs, parameters and instructions, which are stored in the memory 100 under the control of the processor 200. The input interface 300 may be connected to an input device to receive parameters or instructions manually input by a user. The input device may be a touch layer covered on the display screen, a key, a trackball or a touch pad provided on the casing of the terminal, and may also be a keyboard, a touch pad, a mouse, etc.

a display unit 400 connected to the processor 200 and configured to display data processed by the processor 200 and display a user interface for visualization. The display unit 400 may be an LED display, a liquid crystal display, a touch type liquid crystal display, an OLED (organic light emitting diode) touch device, etc.

a network port 500 is connected to the processor 200 and configured to be communicatively connected to each external terminal device. The communication technology used in the communicative connection may be wired communication technology or wireless communication technology, such as mobile HD link technology (MHL), universal serial bus (USB), HD multimedia interface (HDMI), wireless fidelity technology (WiFi), Bluetooth communication technology, low-capacity Bluetooth communication technology, IEEE802.11s based communication technology, etc.

FIG. 5 only shows electronic equipment having the components 100 to 500. It can be understood by those skilled in the art that the structure shown in FIG. 5 does not constitute a limitation on the electronic equipment, and it may include fewer or more components than shown in FIG. 5, or be a combination of some components, or have different component arrangements.

The present disclosure also provides a computer-readable storage medium, which may include U disk, mobile hard disk, read only memory (ROM), random access memory (RAM), magnetic disc or optical disc and other media that can store program codes. A computer program is stored on the storage medium. When the computer program is executed by a processor, the steps of the battery capacity display method disclosed in any of the preceding embodiments are realized.

The present disclosure can judge whether the battery to be detected can be fully charged when the battery is charged at a constant voltage. If it cannot be fully charged, i.e., there is a battery loss, full capacity is displayed via the UI interface when the time duration of the battery in the current capacity state reaches the preset overtime threshold, so that the fully charged state can be still correctly displayed even when there is a battery loss, thereby significantly improving the user experience.

Each embodiment in the specification is described in a progressive manner. Each embodiment focuses on the differences from other embodiments. The same and similar parts of the embodiments can be referred to each other. As for the system disclosed by an embodiment, since it corresponds to the method disclosed by an embodiment, the description is relatively simple. Relevant parts can refer to the description of the method. It should be noted that, for those skilled in the art, certain improvements and modifications can be made to the present disclosure without departing from the principles of the present disclosure, and these improvements and modifications also fall within the protection scope of the claims of the present disclosure.

It should also be noted that, relational terms such as first and second used herein are only to distinguish one entity or operation from another, and do not necessarily require or imply that there is such actual relationship or order among those entities or operations. Moreover, the terms “comprise”, “include” or any other variants are intended to cover non-exclusive inclusion, so that the process, method, article or apparatus including a series of elements may not only include those elements, but may also include other elements not stated explicitly, or elements inherent to the process, method, articles or apparatus. Without more limitations, an element defined by the phrase “comprising a . . . ” does not exclude the case that there are other same elements in the process, method, article or apparatus including the element.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment, it being understood that various changes may be made in the function and arrangement of elements described in an exemplary embodiment without departing from the scope of the invention as set forth in the appended claims and their legal equivalents.

1. A battery capacity display method, comprising:
judging whether a battery to be detected can be fully charged when the battery to be detected is in a constant voltage charging state;
if not, determining a current capacity state of the battery to be detected and monitoring a time duration of the battery to be detected under the current capacity state;
judging whether the time duration is greater than a corresponding preset overtime threshold; and
if the time duration is greater than the preset overtime threshold, displaying full capacity via a UI interface,
after determining the current state of capacity of the battery to be detected, the method further comprises: determining the capacity range in which the capacity value corresponding to the current capacity state is located;
correspondingly, the step of if the time duration is greater than the preset overtime threshold, displaying full capacity via the UI interface comprises:
if the time duration is greater than the preset overtime threshold and the capacity value corresponding to the current capacity state is in a first capacity range, directly displaying full capacity via the UI interface;
if the time duration is greater than the preset overtime threshold and the capacity value corresponding to the current capacity state is in a second capacity range, displaying a first prompt message of battery loss and displaying full capacity via the UI interface; and
if the time duration is greater than the preset overtime threshold and the capacity value corresponding to the current capacity state is in a third capacity range, sending back a second prompt message of serious battery loss and displaying full capacity via the UI interface.

2. The battery capacity display method according to claim 1, wherein judging whether the battery to be detected can be fully charged comprises:
acquiring a current voltage value of the battery to be detected;
judging whether the current voltage value reaches a preset voltage threshold; and
if yes, determining that the battery to be detected can be fully charged.

3. The battery capacity display method according to claim 1, wherein judging whether the battery to be detected can be fully charged comprises:
if the battery to be detected is equipped with a capacity meter, directly acquiring a current capacity value of the battery to be detected obtained by the capacity meter;
judging whether the current capacity value reaches a preset capacity threshold; and
if yes, determining that the battery to be detected can be fully charged.

4. (canceled)

5. The battery capacity display method according to claim 1, wherein after judging whether the battery to be detected can be fully charged, the method further comprises:
if it is determined that the battery to be detected can be fully charged, directly displaying full capacity via the UI interface.

6. The battery capacity display method according to claim 1, further comprising:
collecting a plurality of historical charging curves of the battery to be detected, and determining an initial overtime threshold respectively corresponding to each historical charging curve; and
determining an average value of a plurality of initial overtime thresholds as the preset overtime threshold.

7. A battery capacity display device, comprising:
a first judgment module configured for judging whether a battery to be detected can be fully charged when the battery to be detected is in a constant voltage charging state;
a time monitoring module configured for, if it is determined that the battery to be detected can not be fully charged, determining a current capacity state of the battery to be detected and monitoring a time duration of the battery to be detected under the current capacity state;
a second judgment module configured for judging whether the time duration is greater than a corresponding preset overtime threshold; and
a full capacity display module configured for, if the time duration is greater than the preset overtime threshold, displaying full capacity via a UI interface,
after determining the current state of capacity of the battery to be detected, the method further comprises: determining the capacity range in which the capacity value corresponding to the current capacity state is located;
correspondingly, the step of if the time duration is greater than the preset overtime threshold, displaying full capacity via the UI interface comprises:
if the time duration is greater than the preset overtime threshold and the capacity value corresponding to the current capacity state is in a first capacity range, directly displaying full capacity via the UI interface;
if the time duration is greater than the preset overtime threshold and the capacity value corresponding to the current capacity state is in a second capacity range, displaying a first prompt message of battery loss and displaying full capacity via the UI interface; and
if the time duration is greater than the preset overtime threshold and the capacity value corresponding to the current capacity state is in a third capacity range, sending back a second prompt message of serious battery loss and displaying full capacity via the UI interface.

8. The battery capacity display device according to claim 7, wherein the first judgment module comprises:
an acquisition unit configured for acquiring a current voltage value of the battery to be detected;
a judgment unit configured for judging whether the current voltage value reaches a preset voltage threshold; and
a determination unit configured for determining that the battery to be detected can be fully charged if the current voltage value reaches the preset voltage threshold.

9. Electronic equipment, comprising:
a memory configured for storing a computer program; and
a processor configured for realizing steps of the battery capacity display method according to claim 1 when executing the computer program.

10. A computer-readable storage medium, wherein a computer program is stored on the computer-readable storage medium, and when the computer program is executed by a processor, steps of the battery capacity display method according to claim 1 are realized.

11. The battery capacity display method according to claim 2, further comprising:
collecting a plurality of historical charging curves of the battery to be detected, and determining an initial overtime threshold respectively corresponding to each historical charging curve; and
determining an average value of a plurality of initial overtime thresholds as the preset overtime threshold.

12. The battery capacity display method according to claim 3, further comprising:
collecting a plurality of historical charging curves of the battery to be detected, and determining an initial overtime threshold respectively corresponding to each historical charging curve; and
determining an average value of a plurality of initial overtime thresholds as the preset overtime threshold.

13. The battery capacity display method according to claim 5, further comprising:
collecting a plurality of historical charging curves of the battery to be detected, and determining an initial overtime threshold respectively corresponding to each historical charging curve; and
determining an average value of a plurality of initial overtime thresholds as the preset overtime threshold.

14. Electronic equipment, comprising:
a memory configured for storing a computer program; and
a processor configured for realizing steps of the battery capacity display method according to claim 2 when executing the computer program.

15. Electronic equipment, comprising:
a memory configured for storing a computer program; and
a processor configured for realizing steps of the battery capacity display method according to claim 3 when executing the computer program.

16. Electronic equipment, comprising:
a memory configured for storing a computer program; and
a processor configured for realizing steps of the battery capacity display method according to claim 5 when executing the computer program.

17. Electronic equipment, comprising:
a memory configured for storing a computer program; and
a processor configured for realizing steps of the battery capacity display method according to claim 6 when executing the computer program.

18. A computer-readable storage medium, wherein a computer program is stored on the computer-readable storage medium, and when the computer program is executed by a processor, steps of the battery capacity display method according to claim 2 are realized.

19. A computer-readable storage medium, wherein a computer program is stored on the computer-readable storage medium, and when the computer program is executed by a processor, steps of the battery capacity display method according to claim 3 are realized.

20. A computer-readable storage medium, wherein a computer program is stored on the computer-readable storage medium, and when the computer program is executed by a processor, steps of the battery capacity display method according to claim 5 are realized.

21. A computer-readable storage medium, wherein a computer program is stored on the computer-readable storage medium, and when the computer program is executed by a processor, steps of the battery capacity display method according to claim 6 are realized.
